(19) United States
(12) Patent Application Publication
(10) Pub. No.: US 2024/0251526 A1
(43) Pub. Date: Jul. 25, 2024

(54) Systems and Methods for Creating Flexible and Rigid Pressure Vessels and Thermal and Fluid Devices Made from Amorphous Metals

(71) Applicant: California Institute of Technology, Pasadena, CA (US)

(72) Inventors: Douglas C. Hofmann, Altadena, CA (US); Scott N. Roberts, Altadena, CA (US); Benjamin I. Furst, Altadena, CA (US)

(73) Assignee: California Institute of Technology, Pasadena, CA (US)

(21) Appl. No.: 18/423,219

(22) Filed: Jan. 25, 2024

Related U.S. Application Data
(60) Provisional application No. 63/441,002, filed on Jan. 25, 2023.

(51) Int. Cl. H05K 7/20

(52) U.S. Cl. CPC H05K 7/20336; F28F 2255/02

(57) ABSTRACT

Amorphous metal thermal management devices are described. The amorphous metal thermal management devices are advanced heat transfer systems that utilize the unique properties of amorphous metal to transfer heat away from components that generate heat in numerous applications. These devices feature either rigid or flexible vapor chambers, for dissipating heat and can be used to cool a wide range of devices. The resulting cooling solution is both effective and reliable.

### CROSS-REFERENCE TO RELATED APPLICATIONS

This application claims priority to U.S. Provisional Patent Application No. 63/441,002, filed Jan. 25, 2023, the disclosure of which is incorporated herein by reference.

### FEDERAL SUPPORT STATEMENT

This invention was made with government support under Grant No. 80NMO0018D0004 awarded by NASA (JPL). The government has certain rights in the invention.

### FIELD OF THE INVENTION

This application generally relates to thermal management devices. More specifically, it relates to the use of amorphous metals in both flexible and rigid pressure vessels, thermal and fluid devices, as well as systems and methods for their creation and use.

### BACKGROUND

Thermal management is a crucial process that involves controlling the temperature of a system. Thermal management especially in electronics, to ensure their reliability and prevent premature failure. Electronic devices generate excess heat that requires efficient handling. Thermal transfer is the process of moving heat from one location to another, which can be achieved through conduction, convection, or radiation.

Conductive materials such as copper and aluminum are commonly used to facilitate heat transfer through conduction. On the other hand, vapor chambers employ phase change technologies to achieve superior thermal conductivity compared to solid metals. They effectively spread heat due to their high equivalent thermal conductivity.

Heat pipes are another option that transfers heat between two interfaces using phase transition. At the hot interface, a volatile liquid transforms into vapor by absorbing heat. The vapor then travels through the pipe to the cold interface, where it condenses back into a liquid and releases latent heat.

However, heat pipes have limitations, particularly in high-power situations where addressing thermal challenges may require several pipes. This can lead to increased costs and design restrictions; rigid components like heat pipes and vapor chambers can only provide a limited range of motion, deflection on axes, vibration isolation, and attenuation.

Flexible heat pipes, on the other hand, offer design flexibility and easy integration into thermal systems to enhance cooling efficiency and capacity.

Nevertheless, they may encounter issues such as stiffness and a lack of vibration isolation.

The development of flexible heat pipes and thermal management systems will improve efficiency, longevity, and range of applications for systems that utilize them.

### SUMMARY OF THE INVENTION

Devices and methods in accordance with some embodiments of the invention are directed to amorphous metal thermal management devices and methods for their manufacture and use.

Many embodiments of the disclosure are directed to a thermal transfer device comprising, at least one layer of an amorphous metal film, and a working fluid, wherein the amorphous metal film is configured to enclose a volume, and the volume is sealed such that the working fluid is disposed within the volume, and the working fluid is configured to absorb, transfer, transport, and dissipate heat.

In some embodiments, the volume is pressurized or evacuated to form a vacuum gap.

In various embodiments, the enclosed volume is selectively sealed in a pattern to form a fluid path or provide tensile strength.

In many embodiments, the device is configured to flex without permanent deformation.

In numerous embodiments, the device is configured with bellows, slits, tabs, voids, bends, or various other geometrical shapes that enhance elasticity, flexibility, stiffness, or isolate vibration.

In several embodiments, the device is further configured with bellows, slits, tabs, voids, bends, or various other geometrical shapes to adapt the device to or be positioned around a structure or allow another structure to pass through it.

In many embodiments, the device further comprises a wicking material that is disposed within the volume.

In some embodiments, the device further comprises a catalyst that is disposed within the volume.

In numerous embodiments, the device further comprises at least one material layer.

In many embodiments, the amorphous metal film is further configured as an electrical ground plate.

In some embodiments, the device further comprises at least one material coating wherein the at least one material coating is affixed to at least one surface and the material coatings modifies the hydrophobic, hydrophilic, corrosion, or emissivity property of the at least one surface.

In some embodiments, the device further comprises at least one structure configured to support the voluminous configuration, provide compressive strength, prevent collapse, improve thermal performance, improve fluid flow, or form a fluid path.

In many embodiments, the at least one structure can be configured by plastically or elastically deforming to adopt a conformal shape.

Numerous embodiments of the disclosure are directed to a thermal transfer assembly comprising, at least one enclosed pressure vessel configured with at least one amorphous metal wall, at least one receiving interface disposed at a first point on and thermally coupled to the pressure vessel, at least one radiating interface disposed at a second point on and thermally coupled to the pressure vessel, and a working fluid disposed in the pressure vessel configured to absorb, transfer, transport, and dissipate heat, wherein thermal energy at the receiving interface is transferred through the pressure vessel at the first point, absorbed and transported by the working fluid to the second point, where it is transferred through the pressure vessel to and dissipated by the radiating interface.

In some embodiments, the assembly is coupled to a rigid structure.

In various embodiments, the assembly is integrated into a deployment mechanism.

In some embodiments, the assembly is configured to transfer thermal energy across a plurality of disparate surfaces.

In many embodiments, the device further comprises an external working fluid wherein a plurality of pressure vessels are configured such that the external working fluid transfers thermal energy between the plurality of pressure vessels.

Various embodiments of the disclosure are directed to a method of manufacturing a thermal transfer device comprising, configuring at least one amorphous metal film to enclose a volume, disposing a working fluid configured to absorb, transfer, transport, and dissipate heat within the volume, and sealing the voluminous configuration such that the voluminous configuration forms a fluid path.

In some embodiments, the device further comprises fabricating bellows, slits, tabs, voids, bends, or various other geometrical shapes and seams into the thermal transfer device.

In many embodiments, the method further comprises articulating the device along cutouts and flexible joints to form complex geometries.

In some embodiments, the method further comprises, coupling a plurality of voluminous configurations to form a network.

In several embodiments, the method further comprises, forming or tensioning the device to form a deployment mechanism.

In some embodiments, the method further comprises, configuring at least one structure plastically or elastically to adopt a conformal shape.

In various embodiments, the method further comprises, embedding the device in a structure.

In numerous embodiments, the method further comprises, application of at least one material coating to at least one surface modifying the properties of the at least one surface.

In several embodiments, the method further comprises, mechanically or thermally coupling a material layer.

In some embodiments, the device is configured as a heat pipe or vapor chamber.

In many embodiments, the fluid path is configured as an oscillating heat pipe such that the fluid path oscillates between a first point and a second point.

In some embodiments, the fluid path is configured as an oscillating heat pipe such that the fluid path oscillates between a first point and a second point.

In various embodiments, the wicking material is patterned onto the amorphous metal film.

In several embodiments, the at least one material coating is configured as a wick.

In many embodiments, the device is configured as a rectangle with an aspect ratio of at least 5:1.

In some embodiments, the device is configured as a round shape or oval.

In several embodiments, the total thickness is between 20-500 micrometers.

In various embodiments, the amorphous metal film has a thickness between 10-250 micrometers.

In some embodiments, the voluminous configuration is sealed by welding, brazing, or adhesive.

In numerous embodiments, the welding is capacitive welding, laser welding, thermoplastic welding, ultrasonic welding, or frictional welding.

In various embodiments, the working fluid is selected for minimal corrosion.

In several embodiments, the amorphous metal film is at least 10% amorphous.

In some embodiments, the device is further configured to provide vibration isolation.

In many embodiments, the pattern is a serpentine internal path.

In some embodiments the at least one structure has low conductivity.

In several embodiments the at least one structure is disposed within the volume.

In various embodiments the at least one structure is configured for controlling torsional stiffness.

In numerous embodiments the at least one material layer is Kapton tape.

In some embodiments the at least one material layer is configured for wicking of fluid.

In many embodiments the device is configured to flex without permanent deformation such that the device can be actuated at least 1000 times without failing.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as embodiments of the invention and should not be construed as a complete recitation of the scope of the invention, wherein:

FIGS. 1A through 1F show a flexible thermal strap made by welding amorphous metal sheets in accordance with various embodiments.

FIGS. 2A through 2C depict a method for sealing the edges of a heat exchanger in accordance with various embodiments.

FIGS. 3A through 3C illustrate a fluid-filled cavity in accordance with various embodiments.

FIGS. 4A and 4B show a flexible metallic glass heat exchanger filled with fluid, in accordance with some embodiments.

FIG. 5 illustrates a flexible heat pipe with intermediate layers in accordance with various embodiments.

FIG. 6 shows a flexible thermal strap with hydrophobic and hydrophilic surfaces in accordance with various embodiments.

FIG. 7 depicts stiffening with ribs in accordance with various embodiments.

FIG. 8 shows rolling a flexible heat pipe in accordance with various embodiments.

FIG. 9 depicts a flexible heat pipe being deployed in accordance with various embodiments.

FIGS. 10A through 10F illustrate the fabrication of a flexible heat pipe in accordance with various embodiments.

FIG. 11 depicts a tortuous fluid path heat pipe in accordance with various embodiments.

FIG. 12 shows flexible heat pipe honeycomb composite structures in accordance with various embodiments.

FIG. 13 shows a flexible heat pipe with cutouts for flexibility in accordance with various embodiments.

FIG. 14 shows 3D heat pipes fabricated in accordance with various embodiments.

FIG. 15 depicts geometric shapes that can fold into 3D heat pipes in accordance with various embodiments.

FIG. 16 shows flexible and expandable joints to assist with bending in accordance with various embodiments.

FIG. 17 depicts multiple heat pipes welded to form a network in accordance with various embodiments.

FIG. 18 illustrates the addition of features to construct 3D structures in accordance with various embodiments.

FIG. 19 depicts flexible heat pipes with non-uniform geometries in accordance with various embodiments.

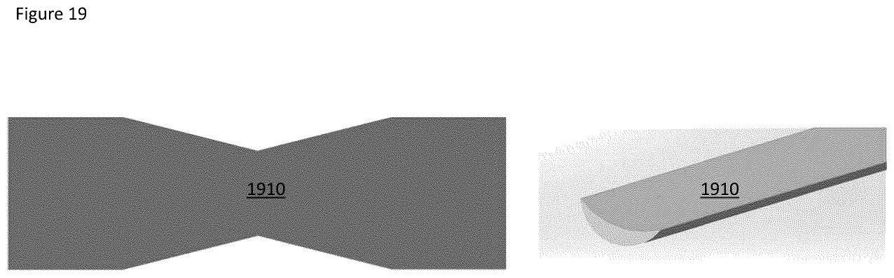

FIG. 20 shows a flexible heat pipe embedded as a layer in a structure in accordance with various embodiments.

### DETAILED DESCRIPTION OF THE INVENTION

Amorphous metals, which are also known as metallic glasses, are a class of metal alloys that possess an amorphous atomic structure. This atomic arrangement results from rapid solidification of the metal alloys without allowing sufficient time for crystallization. This leads to a random yet highly homogenous arrangement of atoms. These alloys exhibit exceptional properties, including high stability, corrosion and wear resistance, and high elasticity, making them versatile and suited for numerous applications. Additionally, amorphous metals demonstrate high tensile strength and can be processed with techniques similar to plastic fabrication, allowing for greater flexibility in manufacturing. These unique properties make them an exciting and promising area of research in various industries, including aerospace, electronics, and healthcare.

A heat pipe is an efficient heat-transfer device that utilizes phase transition to transfer heat between two solid interfaces. It operates based on the principle of evaporation and condensation. The device consists of a sealed, hollow tube that contains a working fluid, which is typically a mixture of water and alcohol.

The heat transfer process begins when one end of the pipe is heated by a heat source, such as a CPU or other electronic device. The working fluid in this section absorbs the heat and turns into a vapor. The vapor then moves to the other end of the tube, which is the condenser section, where it releases the absorbed heat and turns back into a liquid form capillary action, which is the ability of a liquid to flow in narrow spaces without the assistance of, or even in opposition to, external forces like gravity, then returns the liquid to the evaporator section. This process repeats itself continuously, facilitating the rapid transfer of heat from the source to the sink without the use of any external power sources.

Heat pipes are capable of transferring heat several hundred times faster than a solid conductor rod because they rely on the latent heat of vaporization to transfer heat, which involves a much higher heat transfer coefficient than conduction. Heat pipes are used in a wide range of applications, such as cooling of electronics, thermal control of spacecraft, and heat recovery systems, due to their remarkable heat transfer efficiency.

Pressure vessels are containers designed to hold gases or liquids at a pressure level that is different from the surrounding atmospheric pressure. These vessels are typically used in various industries, such as chemical processing, oil and gas, and power generation and for heat pipes. Their design and fabrication involve a range of materials and techniques that are tailored to the intended pressure application, taking into account factors such as vessel size, contents, and operational pressure.

The materials used in the construction of pressure vessels can vary, but most commonly include metals such as stainless steel, carbon steel, and aluminum. These materials are selected based on their strength and resistance to corrosion, as well as their compatibility with the contents of the vessel. The incorporation of amorphous metals into pressure vessel construction has the potential to improve their performance and durability, resulting in safer and more efficient operations in various industries.

### Flexible and Deployable Pressurized Systems

Pressurized fluid systems are usually rigid structures due to the inflexible nature of the materials used in their construction and fabrication, such as steel, copper, nickel, aluminum, and their alloys. Additionally, the thickness and shape of these vessels prevent often further limit any significant flexibility or movement. Some flexible pressure components have been developed by modifying the pressure vessel's geometry, such as the addition of bellows and tubing or the incorporation of additional, more flexible materials such as rubber and hoses. However, these methods have limitations. The use of geometric features to increase the pressure vessel's flexibility is still limited by the rigidity of the materials utilized. Similarly, the use of more flexible non-metallic materials like rubber hoses can result in limitations on the working pressures and operating conditions due to the lower strength of polymers compared to metallic alloys. The lower strength of polymers can be overcome in part by employing thicker materials but doing so would impact the flexibility defeating the reason for their use in place of metallic alloys.

### Flexible Thermal Systems

Fluid-based thermal control systems such as single and two-phase mechanically pumped fluid loops, heat pipes, thermosyphons, and oscillating heat pipes are typically made with rigid metallic materials due to the need for these systems to maintain a set pressure. Traditional heat pipe systems also often utilize sintered porous material, which is typically rigid and brittle, further limiting the flexibility of the system. As such traditional fluid-based thermal control systems are largely rigid systems that have minimal flexibility.

There have been numerous attempts to develop flexible fluid-based thermal control systems. However, these efforts often fall short. Systems that use polymers for flexibility frequently fail to maintain hermetic seals. On the other hand, systems that use traditional metallic alloys are constrained by the inherent rigidity of these materials. Even with the incorporation of metal bellows or flexible segments in rigid heat pipes, the flexibility of these systems is still limited.

Strap-based thermal control systems often employ thermal straps that are made from braided metal cables, thin metal sheets, or thin graphite (Kcore). These systems have moderate thermal performance and are conduction-based. Traditionally flexible thermal control elements such as copper heat straps have limited performance (compared to heat pipes) as well as significant constraints on their flexibility.

Thermal straps with increased flexibility have been made using polymers, Kapton being one example. In some cases, these have been used as roll-up (or out) radiators. However, these devices often face challenges. They tend to have limited durability and performance, and they can have difficulties maintaining their seals or withstanding substantial pressure.

### Rigid Thermal Systems

Traditional thermal control systems, such as heat exchangers, typically use an arrangement of metallic components to create a system that enables heat transfer between two separate fluid streams. One common type of heat exchanger is the flat plate heat exchanger, which uses a sequence of thin metal plates to create separate flow paths and transfer heat between two fluids. These plates are often made from conventional alloys, which can require significant thickness to withstand pressure differentials between the fluids and surrounding environment, and in turn, this thickness can reduce the overall efficiency of the heat exchanger.

Traditional vacuum-based insulation typically uses rigid materials, such as metal or glass, to create an insulating vacuum gap. The thickness of these vacuum walls is largely determined by material constraints and must be thick enough to maintain adequate strength or hermeticity.

Multi-layer insulation (MLI) is an alternative that uses flexible polymer-based materials to create a radiation shield in a vacuum environment. However, MLI is limited in its usage due to its being a polymer. Traditional metallic-based radiation shields using metal materials have their own set of limitations based on limited flexibility and weight.

For all of the thermal systems discussed above, there is a need for a solution that combines ultra-thin materials that can effectively contain and transfer pressurized fluid while still being able to maintain flexibility, withstand various environmental conditions, and maintain the required properties for their application, such strength, fatigue life, toughness, temperature range, and corrosion resistance.

### Amorphous Metal Fabrication

Amorphous metal ribbon has been utilized for decades as a material used in transformer cores and as a thin foil for brazing. Amorphous metal ribbons are most often produced through melt-spinning into sheets and are commercially available with thicknesses from 10-250 micrometers and widths of a few millimeters to hundreds of millimeters. Amorphous metal ribbons have been welded together to fabricate numerous useful products, utilizing numerous fabrication techniques such as through laser welding, ultrasonic consolidation, or thermoplastic consolidation.

As discussed above, amorphous metal ribbons are highly versatile and useful for a variety of applications. For many applications, amorphous metal ribbons are most effective when they are joined together across their entire surface area to create larger structures and integrate them into products. Magnetic amorphous metals, for example, are often used in transformers. In such applications, the magnetic amorphous metals are wound and then bound with fillers to create magnetic laminates used in transformers.

In other applications, amorphous metal ribbons are integrated by brazing; the amorphous metal ribbons are inserted between two other metals, melted, and welded together completely to create a solid connection between the two materials.

Laser foil printing is another fabrication technique used to create 3D objects from amorphous metal sheets. By joining multiple layers of these sheets, laser foil printing can achieve near-complete consolidation (>99%).

Yet another fabrication process adopted to join amorphous metal ribbons to substrates is ultrasonic welding. This process bonds the materials together and creates coatings.

By leveraging the broad range of fabrication and joining techniques, available amorphous metal components have been employed across an extensive array of applications. For example, amorphous metals are ideal for applications where flexible mechanisms such as compliant mechanisms, springs, and other flexible structures are required. Amorphous metals are suitable for these applications because they possess a high elastic limit and high energy storage, and thin sections can be fabricated that can be bent, articulated, and flexed without exceeding their yield strength.

Amorphous metal structures are predominately designed for elastic deformation. Amorphous metals are not a material selection that would normally be made for enclosing a volume. The process of creating an enclosed volume from amorphous metals restricts the resulting structures' flexibility and motion. The result is a less flexible structure, which is contrary to the predominant motivation, i.e., a flexible structure that amorphous metals are predominately selected for. As a result, careful consideration needs to be paid to the design of the amorphous metal thermal system to simultaneously allow for fluid to be retained inside a volume while also allowing for flexibility.

Similarly, amorphous metals are not a material choice often selected for conducting heat. Using amorphous metal alone for thermal conductivity provides significantly lower results than typical materials selected for their thermal properties, such as aluminum and copper. Likewise, amorphous metals are not a material choice often selected for conducting heat through an internal volume, fluid transport, or in a two-phase solution as amorphous metal provides significantly lower results than a traditional two-phase solution. As a result, amorphous metals have not previously been utilized to fabricate enclosed volumes for pressure vessels and thermal systems, let alone to fabricate enclosed volumes that retain the inherent flexibility of the amorphous metal and contain working fluids for thermal management.

### Embodiments

This disclosure includes several embodiments directed to the use and manufacture of thin, flexible hermetic vessels made of amorphous metal. In accordance with numerous embodiments, these vessels are engineered to withstand a pressure differential and contain fluids or vacuum while also offering a range of desirable properties that make them well-suited for various applications.

In accordance with many embodiments, these vessels have remarkable flexibility and thinness, making them ideal for a wide range of systems and devices. For instance, various embodiments are directed to two-phase thermal control devices such as thermosyphons and heat pipes and other applications that require flexible vessels that can adapt to changes in temperature and pressure.

Additional embodiments are directed toward vessels that are employed in compliant fluid transport system components like transport lines and vessels, which demand precision and durability to ensure the safe and efficient transfer of fluids.

Further embodiments are used in vacuum insulation and radiation shields, where their unique properties make them an exceptional choice for shielding sensitive equipment and materials from environmental factors.

In accordance with many embodiments, these vessels can be fabricated by fusing thin sheets of amorphous metal or fusing thin sheets of amorphous metal fused with other materials, including other amorphous metal, crystalline materials, or various other metals and polymers in layers. In accordance with many such embodiments, the materials are then hermetically sealed to enclose volumes, which can yield a pressurized fluid thermal system that is highly robust and efficient.

Amorphous metal vessels, in accordance with many embodiments, possess an array of highly desirable properties that make them an excellent choice for use in flexible pressurized thermal and fluid systems. Amorphous metals inherently contain properties that make them ideal for flexible pressurized thermal/fluid systems, including nearly 2 GPa yield strength, 2% elastic strain limit, corrosion resistance, variable thickness manufacturing processes, a wide variety of alloy combinations, wear resistance, high hardness, and toughness below a certain thickness. By harnessing the properties of Amorphous metal, in accordance with many embodiments, it is possible to produce vessels that are not only highly efficient and durable but also versatile and customizable to meet specific application requirements.

In accordance with various embodiments, amorphous metal pressure systems (AMPS) are created by welding together amorphous metal ribbons to enclose fluid volumes that can efficiently move and conduct fluid and heat. According to many such embodiments AMPS are employed as a flexible and robust fluid transport element that can be used as heat pipes.

In accordance with many embodiments, thin sheets of amorphous metal film are sealed to create 3D fluid channels. In many such embodiments, the thin sheets of amorphous metal film are sealed using welding, thermoplastic sealing, or ultrasonic consolidation.

In accordance with numerous embodiments, the end result is a thin, stowable, and deployable fluid transport element or heat pipe that is fatigue-resistant. Many embodiments can be fabricated by utilizing commercially available and low-cost and mass-produced amorphous metal ribbons. Numerous such embodiments utilize commercially available amorphous metal ribbons ranging from 10-250 micrometers in thickness to produce economic AMPS with flexibility and mechanical robustness which makes them desirable for use in a variety of applications.

In accordance with numerous embodiments, AMPS can be fabricated from a wide variety of amorphous metal ribbons, thin sheet metal products, and polymer combinations. Numerous embodiments utilize Zr, Cu, Ti, Fe, Ni, and Co ribbons in flat or dimensional form factors. For many embodiments, the ideal alloy material combination for this form of fabrication has a yield strength greater than 1.5 GPa, an elastic limit greater than 1.5%, and a hardness greater than 300 Hv. For such embodiments, these alloys are ideal because they are tough at their manufactured thickness and are robust enough to endure both the welding process to form proper hermetic seals and the repeated flexing and articulation they need to perform for their intended application.

Additionally, in some embodiments, AMPS are created using specialty amorphous alloys and material combinations, such as hypoeutectic alloys, amorphous metal matrix composites, or a combination of amorphous metals with other materials to form multi-material flexible thermal straps. In many embodiments, the flexible structures produced are able to withstand in excess of 1000 articulation cycles before they fracture or experience other system failures.

In accordance with numerous embodiments, AMPS provide a highly versatile solution for fluid transport and heat exchange that offers flexibility, robustness, and cost-effectiveness. Such embodiments' ability to withstand repeated flexing and perform under challenging conditions make it an excellent option for a wide variety of applications.

### Exemplary Embodiments

This disclosure includes several embodiments directed to the use and manufacture of thin, flexible hermetic vessels made of amorphous metal. In accordance with numerous embodiments, the manufacturing process of AMPS relies on an understanding of the manufacturing limitations of amorphous materials, which are non-crystalline, glassy metals.

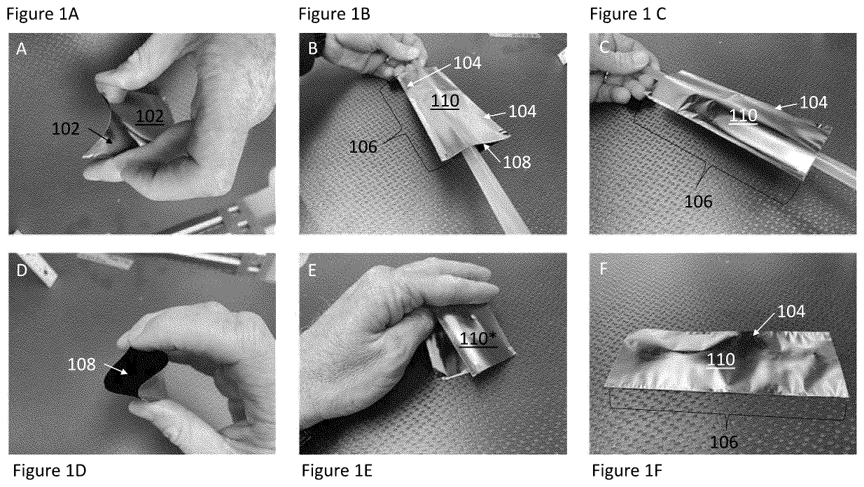

In an exemplary embodiment depicted in FIGS. 1A through 1F, amorphous metal sheets 102 with a thickness of less than 250 micrometers are hermetically sealed 104 along a path 106 that encloses a cavity 108 while still allowing the structure 110 to be flexible 110*.

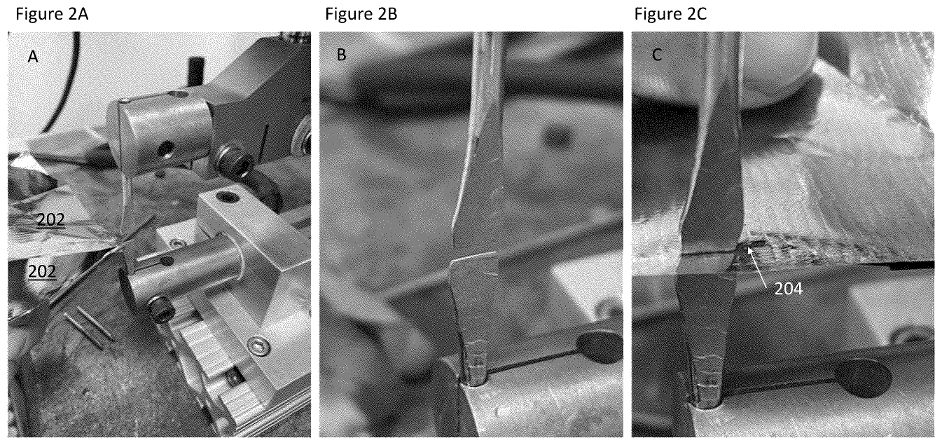

In many embodiments and as depicted in the exemplary embodiment shown in FIGS. 2A through 2C, require that the sealing process does not disrupt the amorphous meatal sheet 202 microstructure without becoming crystalline, and thus brittle. In many embodiments, the seals 204 are fabricated through laser welding, ultrasonic consolidation, thermoplastic sealing, or spot welding, where the alloy is heated, joined, and cooled sufficiently rapidly such that significant crystallization is avoided.

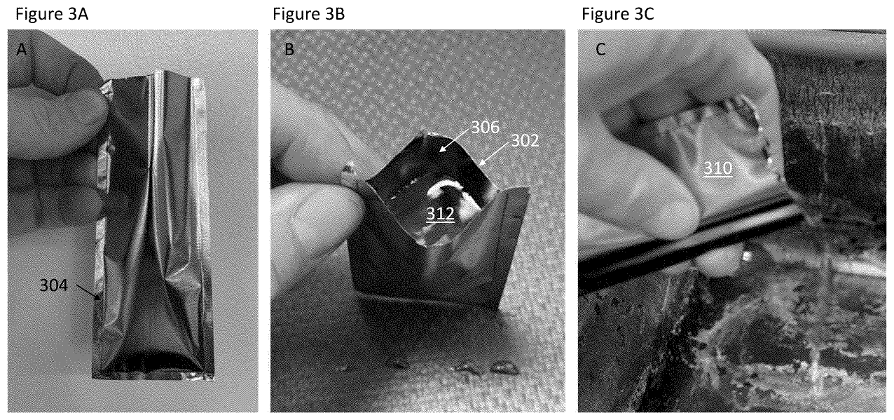

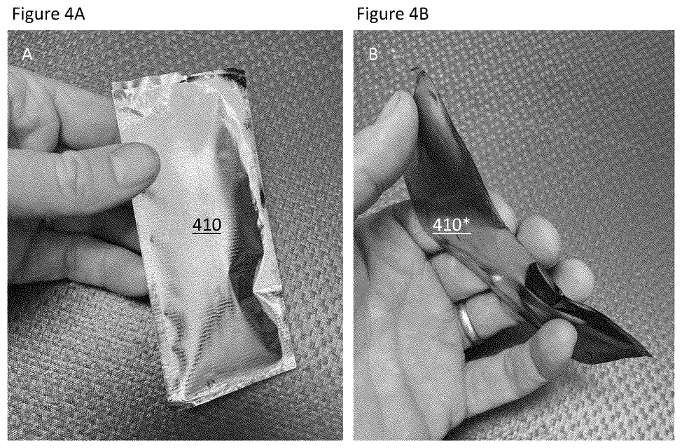

In accordance with numerous embodiments and shown by an exemplary embodiment depicted in FIGS. 3A through 3C by only sealing 304 the amorphous metal ribbon 302 around the perimeter, a discrete volume 306 can be formed within the amorphous metal structure 310 that can be used to enclose a working fluid 312 within the amorphous metal structure 310. In accordance with numerous such employments and shown by the exemplary embodiment in FIGS. 4A and 4B, the fully sealed amorphous metal structure 410 containing the working fluid still maintains significant flexibility 410*.

In accordance with numerous embodiments, in order to achieve a combination of efficient thermal transfer, flexibility, and mechanical robustness, it is necessary to carefully design the enclosed volume. In many such embodiments, the fully enclosed volume is pressurized or evacuated to further tailor the structure's properties to its intended applications.

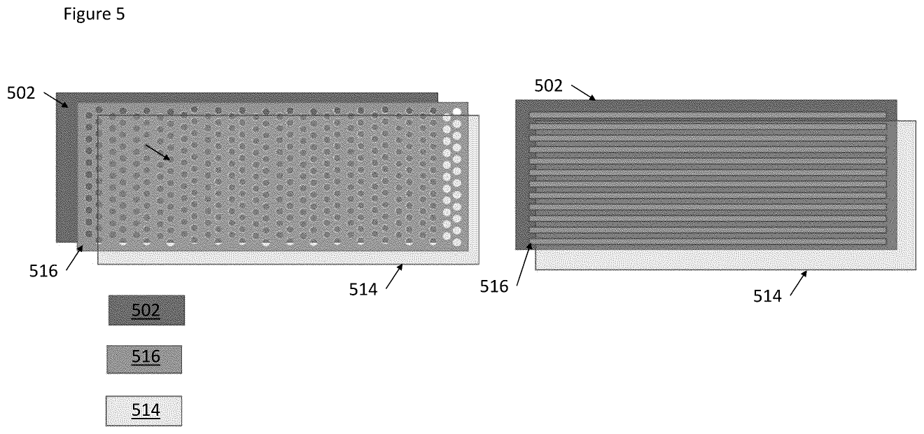

Some embodiments such as the exemplary embodiment depicted in FIG. 5, utilize additional materials layers 514 in addition to the amorphous metal layer 502. Some such embodiments further utilize intermediate layers 516 in addition to top 502 and bottom layers 514 for additional functionality such as wicking the working fluid or structural support.

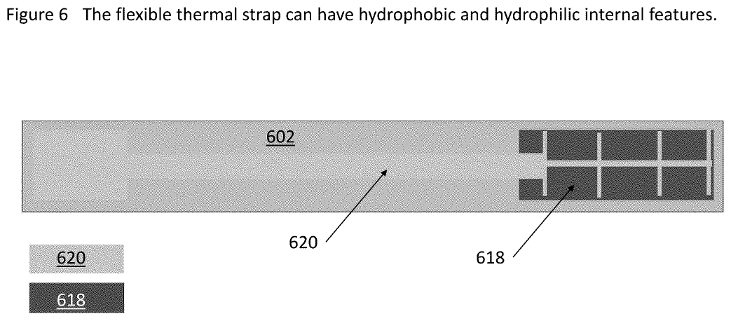

Additional embodiments add additional materials and coating for improved performance or add additional functionality, as illustrated in the exemplary embodiment depicted in FIG. 6, where hydrophilic 616 and hydrophilic 614 sections are applied to the amorphous metal film 502 (or other material layers) to aid in fluid transport, pulling liquid toward the evaporator section and encouraging condensation, respectively. In many embodiments, the material coating is applied chemically, by laser, or thermoplasticly formed, and in numerous such embodiments, the material coatings are applied to the amorphous metal film 602 or other material film layer early in the fabrication process and while the layer films are relatively two dimensional for simplified application and efficiency. In many such embodiments the material coatings are applied prior to sealing together the film layers.

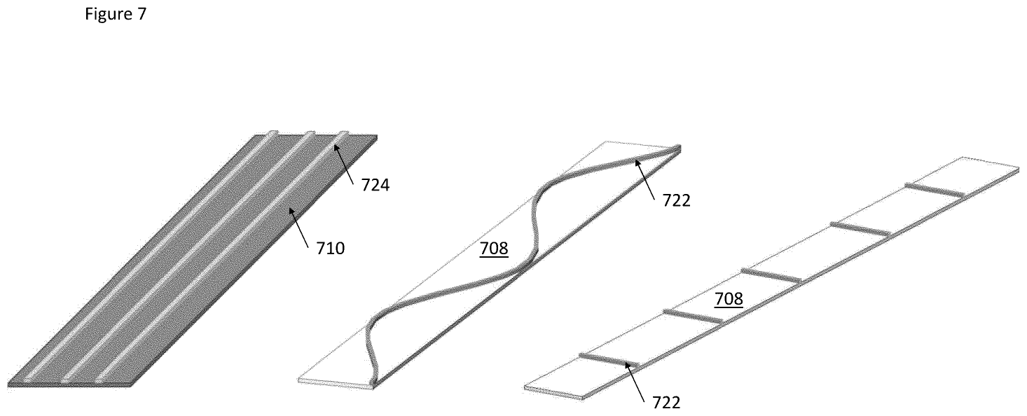

Additional embodiments add additional internal elements 722 inside the cavity enclosed volume cavity 708 or external elements 724 affixed to the exterior of the structure 710 to improve performance or add additional functionality, as illustrated in FIG. 7. For example, some such embodiments enclose wicking materials or baffles inside the cavity 708 to direct, separate, or segment the working fluid. In other examples, some employment employs ribs or spars internally or externally to provide mounting points, rigidity, or control torsional stiffness. In some embodiments, the internal and external elements are designed to deform plastically or elastically such that the structure can be adapted to hold or conformal to a particular arrangement or shape.

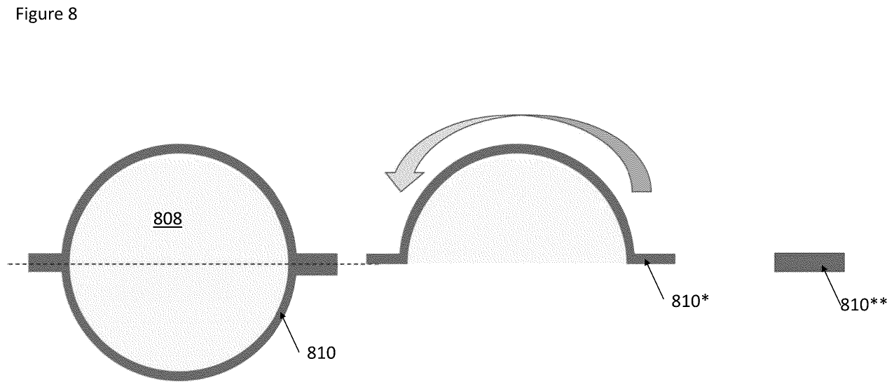

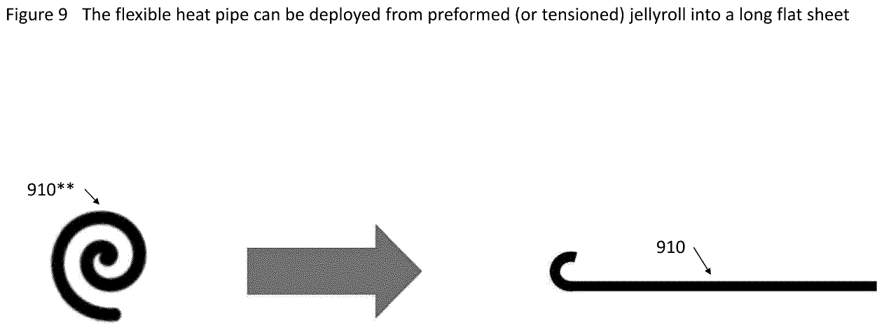

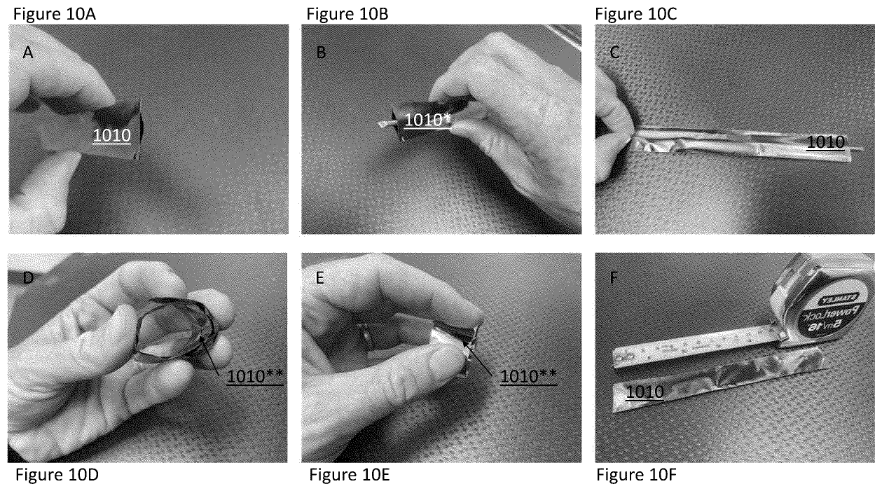

Yet other embodiments utilize the innate flexibility and elastic properties to form flexible structures that can roll, unroll, and articulate without plastic deformation for deployable applications such as the exemplary embodiments depicted in FIGS. 8 through 10. In such embodiments, the structure 810 and internal cavity 808 can be flexed, folded 810*, and rolled 810** without permanent deformation. Many such embodiments form deployable structures that are preformed or tensioned such that a rolled structure 910** articulates or unrolls into a desired expanded structure 910. FIGS. 10A through 10F depict an exemplary employment where structure 1010, made from amorphous metal films (FIG. 10A) is flexed (FIG. 10B) for a fabrication step and reverted to its original configuration for further fabrication (FIG. 10C). Subsequently, the finished device is rolled 1010** compact (FIGS. 10D & 10E) and deployed, restoring its original structure 1010 (FIG. 10F).

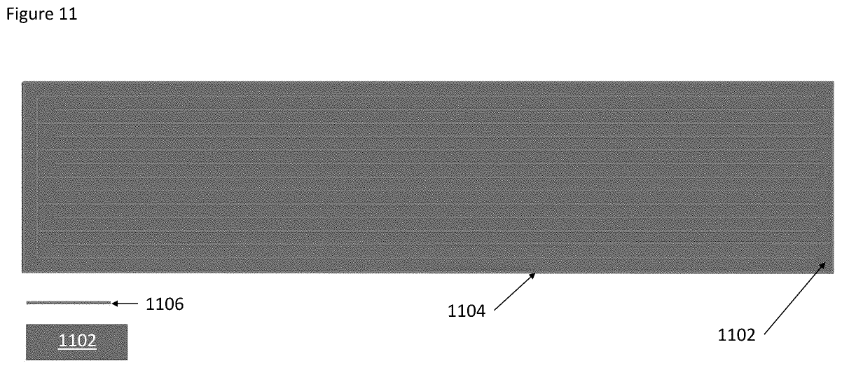

Further embodiments, such as the exemplary embodiment depicted by FIG. 11, selectively seal 1104 the amorphous metal film 1102 or other layers to form a winding path 1106 or loop, creating a “tortuous” fluid path to direct, separate, or segment the working fluid. In other such embodiments, disparate cavities that can be separately evacuated or pressurized are formed from selectively sealing along a path to segment the enclosed volume. In many embodiments, these cavities are utilized to add further flexibility or stiffness. In some embodiments insulating features are added by evacuating select segmented cavities to generate vacuum-insulation.

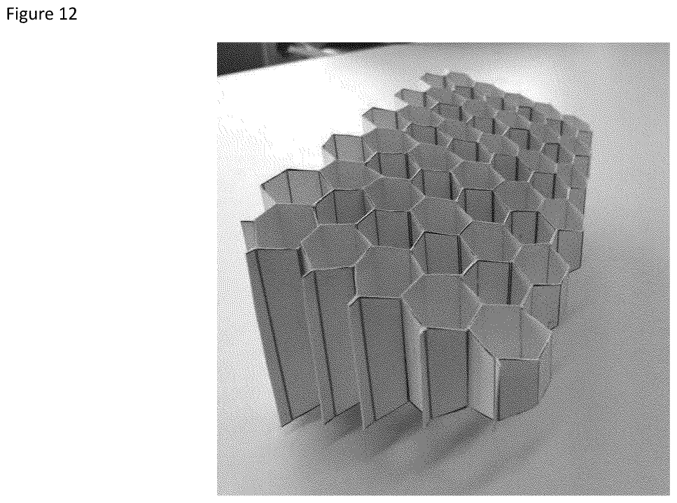

In numerous embodiments, multiple material layers and sequentially sealed in disparate portions such that the material layers can subsequently be expanded to form complex geometric arrangements such as the honeycomb structure depicted in FIG. 12. Many such embodiments are utilized to form a composite structure with integrated cool paths.

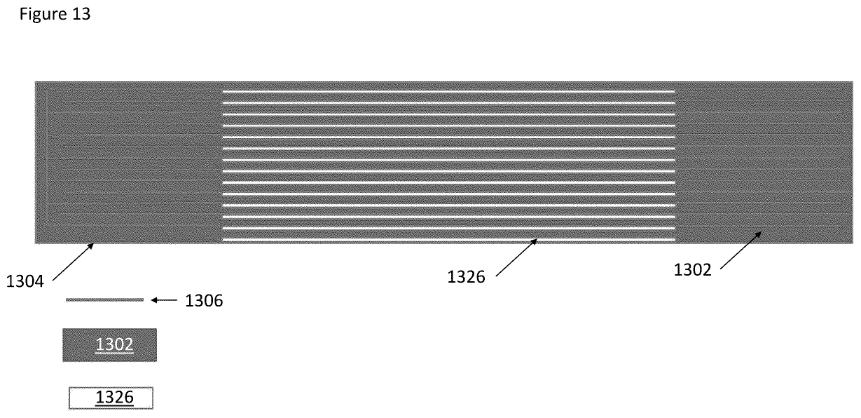

Various embodiments, such as the exemplary embodiment depicted in FIG. 13, further employ voids 1326 to direct, separate, or segment portions of the device. In numerous such embodiments, the void is employed to add further flexibility or insulation between fluid paths. In many embodiments, sealing 1304, the amorphous metal film 1302, fabrication of the void 1326, and forming fluid paths by selectively sealing a patterned or path 1306 can be performed simultaneously. In some such embodiment the sealing 1204 and cutting for the voids 1326 are performed by a laser. In other embodiments, cutting the voids 1326 is performed separately by water jets or other cutting instruments.

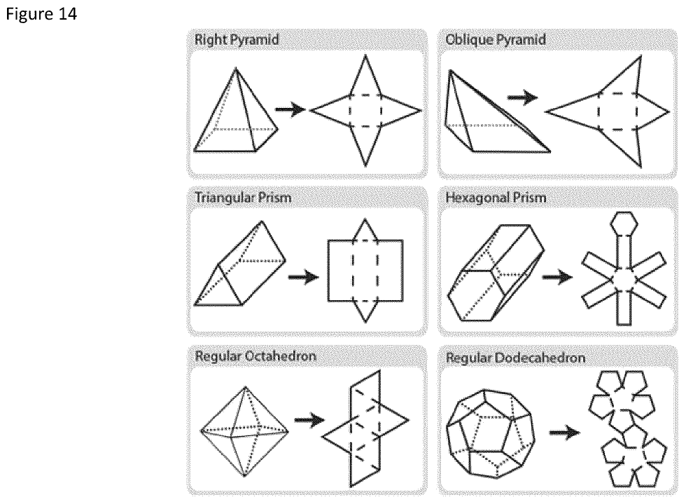

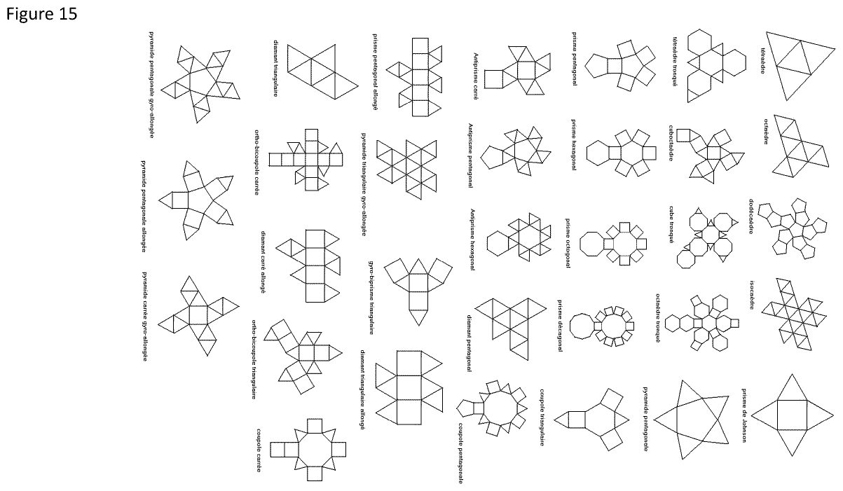

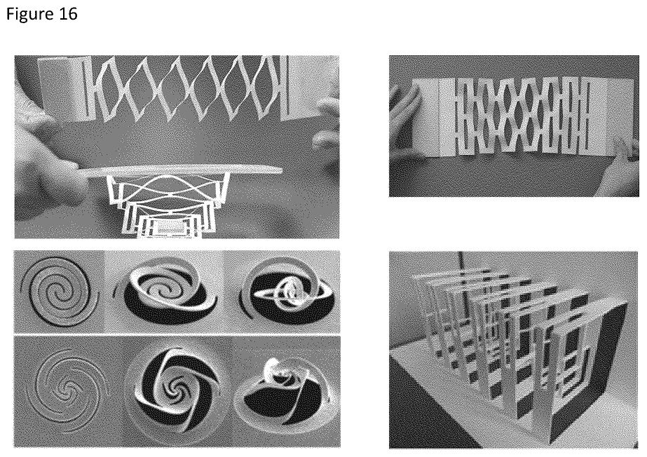

Further embodiments utilize creating slits cuts, and voids to create complex shapes such as the geometrical structures depicted in FIGS. 14 and 15 or complex bending, flexing, and expandable joints as illustrated by the structure in FIG. 16. In many such embodiments by employing spirals and flexures such as those depicted in FIG. 16 is possible to move heat across joints and thermally connect disparate planes.

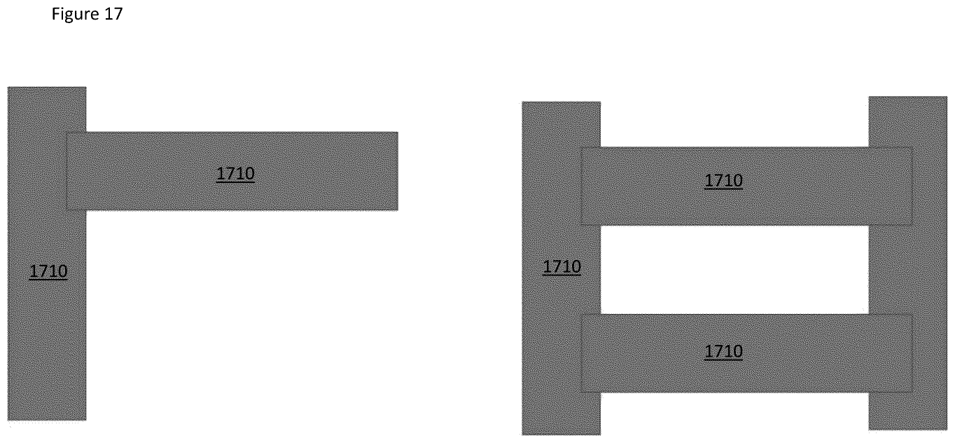

In other embodiments, such as the exemplary embodiments illustrated in FIG. 17, numerous amorphous metal structures 1710 are combined to form networks of flexible heat pipes. In some such embodiments, the disparate structures 1710 that make up the network are welded or sealed together to form the superstructure.

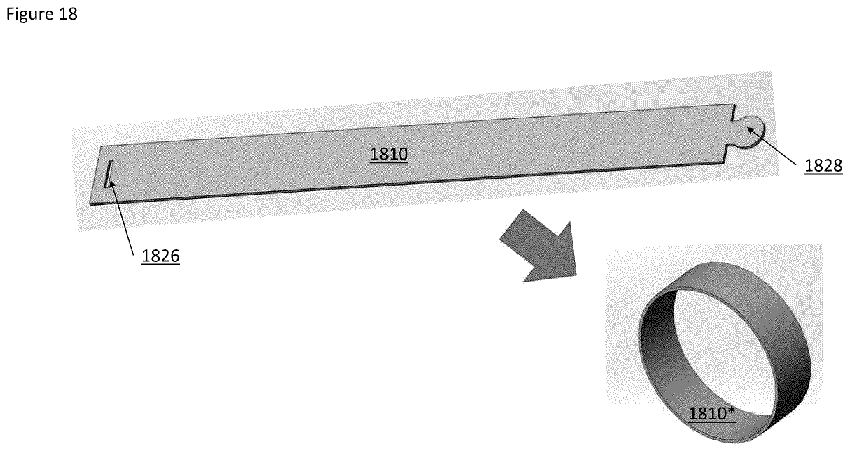

In other embodiments, such as the exemplary embodiment illustrated in FIG. 18, complementary voids 1826 and tabs 1828 or other features are utilized to form networks or to flex the structure 1810* into complex geometries.

In yet other embodiments, non-uniform geometries such as those illustrated in Figure are utilized for the device structure 1910 to suit particular applications or assist in the construction and integration into superstructures and networks with complex geometries.

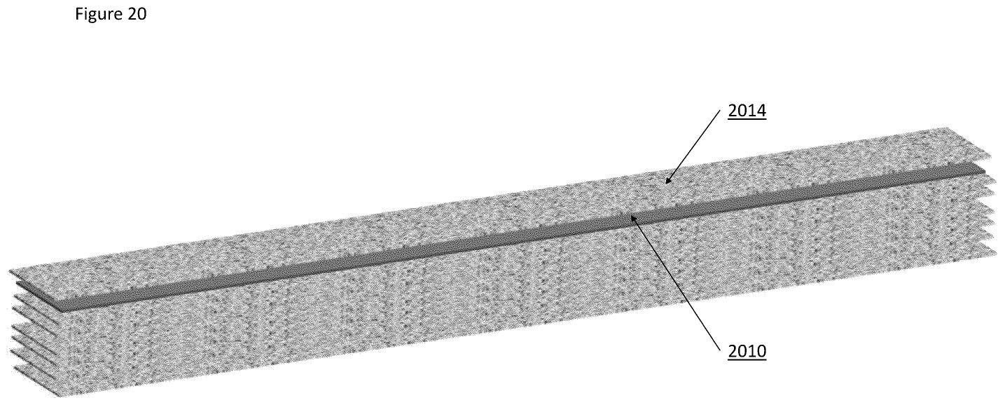

In various embodiments, such as the exemplary embodiment illustrated in FIG. 20, one or many devices 2010 can be embedded in disparate structures or material layers 2014 of a larger superstructure. In many such embodiments, this allows for the integration of a highly conductive layer or multiple layers to control the thermal conductivity of the superstructure. In other such embodiments, the embedded layer can further function as a grounding plate with vias for pass-throughs, adding additional functionality in applications such as circuit boards and allowing for non-rectilinear boards.

### Exemplary Applications

As electronic devices continue to become smaller and more powerful, the challenge of dissipating the heat generated in these tight spaces becomes increasingly critical. The proper management of heat is especially vital in mobile electronic devices, where excessive heat can negatively impact the user's comfort and device performance.

To address this issue, various heat dissipation techniques have been developed, including traditional heat sinks made from graphite and metal sheets. However, these methods are no longer sufficient for many modern devices. Ultra-thin vapor chambers provide a passive solution to help spread thermal energy within mobile devices and maintain a comfortable skin temperature.

In mobile devices, natural convection cooling from the device's chassis is the primary method used to dissipate heat, and a combination of heat pipes, thermal pads, and spreader plates are employed for thermal management. These components work together to transfer heat away from the source and distribute it throughout the device, allowing for effective cooling.

Flexible heat pipes that can bend without compromising cooling efficiency are necessary for foldable electronics. Concentrated heat-generating components in one section of a foldable device can be limited by effective heat transport through articulating joints, making it challenging to manage thermal energy effectively. However, few devices transfer heat from the high heat-generating components on the motherboard across articulating joints, meaning much of the device's surface area is not utilized in cooling flexible devices. To maximize the cooling potential of these flexible devices, it is crucial to distribute the thermal energy generated across the entire device.

Efficient heat management in electronic devices is critical for the next generation of devices, and the development of efficient, flexible heat pipes will be a significant improvement. By using flexible heat pipes and advanced heat dissipation techniques, electronic devices can continue to become smaller, more powerful, and more convenient, without sacrificing performance or user comfort.

The disclosure includes several embodiments directed toward flexible fluid and thermal systems made from amorphous metals. Flexible fluid and thermal systems made from amorphous metals have numerous potential commercial, space, military and consumer applications.

Flexible fluid and thermal systems made from amorphous metals consumer applications include consumer electronics, such as laptop cases, cell phones, battery cases, TVs, monitors, tablets, and displays. Flexible fluid and thermal systems made from amorphous metals also have applications in toys, sporting goods, composite structures, boats, crossflow heat exchangers, robotic arms, cars, vibration isolation devices, 3D printers, audio equipment, and internal clothing heat management.

Flexible fluid and thermal systems made from amorphous metals have applications in aerospace, drones, aircraft, adaptive wings, shape-changing aerial vehicles, and spacecraft. Flexible fluid and thermal systems made from amorphous metals can also be used in deployable spacecraft structures, such as deployable radiators, in robotic arms, and on landers, long deployable heat pipes, cold vacuum heat pipes, and for solar thermal heat transfer, to control thermal energy in flexible structures or other thermally critical structures.

### DOCTRINE OF EQUIVALENTS

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A thermal transfer device comprising,
at least one layer of an amorphous metal film, and a working fluid,
wherein the amorphous metal film is configured to enclose a volume, and the volume is sealed such that the working fluid is disposed within the volume, and the working fluid is configured to absorb, transfer, transport, and dissipate heat.

2. The device of claim 1, wherein the volume is pressurized or evacuated to form a vacuum gap.

3. The device of claim 1, wherein the enclosed volume is selectively sealed in a pattern to form a fluid path or provide tensile strength.

4. The device of claim 1, wherein the device is configured to flex without permanent deformation.

5. The device of claim 1, wherein the device is configured with bellows, slits, tabs, voids, bends, or various other geometrical shapes that enhance elasticity, flexibility, stiffness, or isolate vibration.

6. The device of claim 1, wherein the device is further configured with bellows, slits, tabs, voids, bends, or various other geometrical shapes to adapt the device to or be positioned around a structure or allow another structure to pass through it.

7. The device of claim 1 further comprising a wicking material that is disposed within the volume.

8. The device of claim 1 further comprising a catalyst that is disposed within the volume.

9. The device of claim 1, further comprising at least one material layer.

10. The device of claim 9, wherein the amorphous metal film is further configured as an electrical ground plate.

11. The device of claim 1, further comprising at least one material coating wherein the at least one material coating is affixed to at least one surface and the material coatings modifies the hydrophobic, hydrophilic, corrosion, or emissivity property of the at least one surface.

12. The device of claim 1, further comprising at least one structure configured to support the voluminous configuration, provide compressive strength, prevent collapse, improve thermal performance, improve fluid flow, or form a fluid path.

13. The device of claim 12, wherein the at least one structure can be configured by plastically or elastically deforming to adopt a conformal shape.

14. A thermal transfer assembly comprising,
at least one enclosed pressure vessel configured with at least one amorphous metal wall, at least one receiving interface disposed at a first point on and thermally coupled to the pressure vessel, at least one radiating interface disposed at a second point on and thermally coupled to the pressure vessel, and a working fluid disposed in the pressure vessel configured to absorb, transfer, transport, and dissipate heat,
wherein thermal energy at the receiving interface is transferred through the pressure vessel at the first point, absorbed and transported by the working fluid to the second point, where it is transferred through the pressure vessel to and dissipated by the radiating interface.

15. The assembly of claim 14, wherein the assembly is coupled to a rigid structure.

16. The assembly of claim 14, wherein the assembly is integrated into a deployment mechanism.

17. The assembly of claim 14, wherein the assembly is configured to transfer thermal energy across a plurality of disparate surfaces.

18. The assembly of claim 14, further comprising an external working fluid wherein a plurality of pressure vessels are configured such that the external working fluid transfers thermal energy between the plurality of pressure vessels.

19. A method of manufacturing a thermal transfer device comprising,
Configuring at least one amorphous metal film to enclose a volume, disposing a working fluid configured to absorb, transfer, transport, and dissipate heat within the volume, and sealing the voluminous configuration such that the voluminous configuration forms a fluid path.

20. The method of claim 19, further comprising, fabricating bellows, slits, tabs, voids, bends, or various other geometrical shapes and seams into the thermal transfer device.

21. The method of claim 20, further comprising articulating the device along cutouts and flexible joints to form complex geometries.

22. The method of claim 19, further comprising, coupling a plurality of voluminous configurations to form a network.

23. The method of claim 19, further comprising, forming or tensioning the device to form a deployment mechanism.

24. The method of claim 19, further comprising, configuring at least one structure plastically or elastically to adopt a conformal shape.

25. The method of claim 19, further comprising, embedding the device in a structure.

26. The method of claim 19, further comprising, application of at least one material coating to at least one surface modifying the properties of the at least one surface.

27. The method of claim 19, further comprising, mechanically or thermally coupling a material layer.

28. The device of claim 1, wherein the device is configured as a heat pipe or vapor chamber.

29. The device of claim 3, wherein the fluid path is configured as an oscillating heat pipe such that the fluid path oscillates between a first point and a second point.

30. The device of claim 12, wherein the fluid path is configured as an oscillating heat pipe such that the fluid path oscillates between a first point and a second point.

31. The device of claim 7, wherein the wicking material is patterned onto the amorphous metal film.

32. The device of claim 11, wherein the at least one material coating is configured as a wick.
